(19) United States
(12) Patent Application Publication
(10) Pub. No.: US 2017/0045553 A1
(43) Pub. Date: Feb. 16, 2017

(54) CLAMPING AND PROBING DEVICE

(71) Applicant: BESTEST INDUSTRIAL CO., LTD., New Taipei City (TW)

(72) Inventor: KEN-CHAO CHANG, New Taipei City (TW)

(21) Appl. No.: 14/824,085

(22) Filed: Aug. 12, 2015

(51) Int. Cl. G01R 1/067; G01R 31/28

(52) U.S. Cl. CPC G01R 1/06788; G01R 31/28

(57) ABSTRACT

A clamping and probing device contains first and second probing members. The first probing member contains a first cable, a first coupler in an upper portion on a front side, and a first probe at a bottom end of the first probing member. The first cable is housed inside the first probing member having one end connected to the first probe and another end extended out of a top end of the first probing member. The second probing member contains a second cable, a second coupler in an upper portion on a front side, and a second probe at a bottom end of the second probing member. The second cable is housed inside the second probing member having one end connected to the second probe and another end extended out of a top end of the second probing member.

### BACKGROUND OF THE INVENTION

(a) Technical Field of the Invention

The present invention is generally related to electronic testing devices, and more particular to a device that can be separated into two probing devices and, when assembled, can be used as a clamping and measuring device.

(b) Description of the Prior Art

Following the rapid technology development of semiconductor industry and the trend of seeking even more convenience, most electronic components are getting smaller and lighter.

Electronic components, especially the surface mounted devices (SMDs), are usually welded to the soldered dots on a circuit board, and they are usually checked by probes. When some component has to be replaced, the operator has to switch between a number of tools before finishing the job.

As the electronic components are welded, their replacement requires not only a soldering iron but also a clamping device. After the replacement, the new component has to be checked again using probes so as to assure its proper function. The repeated switching between tools increases the operator's workload.

### SUMMARY OF THE INVENTION

Therefore, to improve operator efficiency and to reduce the time of switching tools, a novel clamping and probing device is provided herein. The clamping and probing device contains plural probing members joined together through simple mechanism. When separated, each probing member can be used individually as test or measurement probe whereas, when put together into a single device, the device can be used as a damper or a fixture.

The clamping and probing device contains first and second probing members. The first probing member contains a first cable, a first coupler in an upper portion on a front side, and a first probe at a bottom end of the first probing member. The first cable is housed inside the first probing member having one end connected to the first probe and another end extended out of a top end of the first probing member. The second probing member contains a second cable, a second coupler in an upper portion on a front side, and a second probe at a bottom end of the second probing member. The second cable is housed inside the second probing member having one end connected to the second probe and another end extended out of a top end of the second probing member.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective diagram showing a clamping and probing device according to an embodiment of the present invention.

FIG. 2 is a perspective break-down diagram showing the clamping and probing device of FIG. 1.

FIG. 3 is a perspective diagram exposing the inside of the clamping and probing device of FIG. 1.

FIG. 4 is a perspective diagram showing the clamping and probing device of FIG. 1 separated into two probing members.

FIG. 5 is a perspective diagram showing a scenario of the clamping and probing device of FIG. 1 functioning as a clamping device.

FIG. 6 is a perspective diagram showing another scenario of the clamping and probing device of FIG. 1 functioning as a clamping device.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

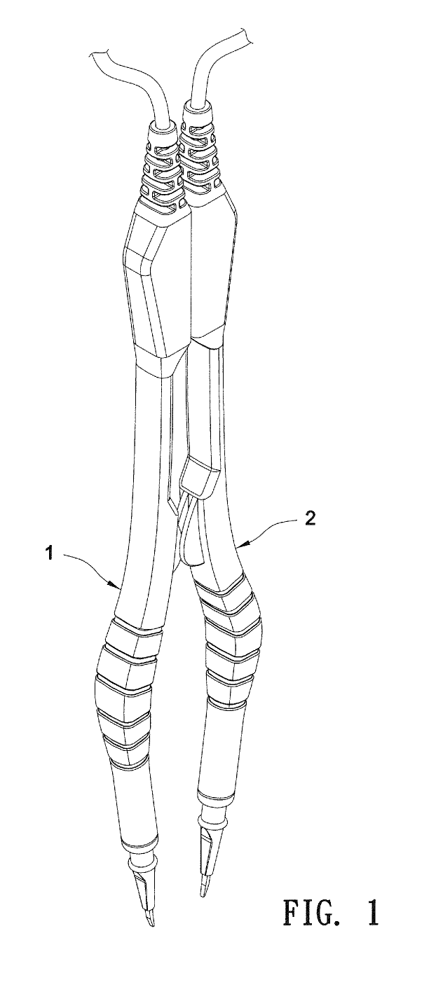

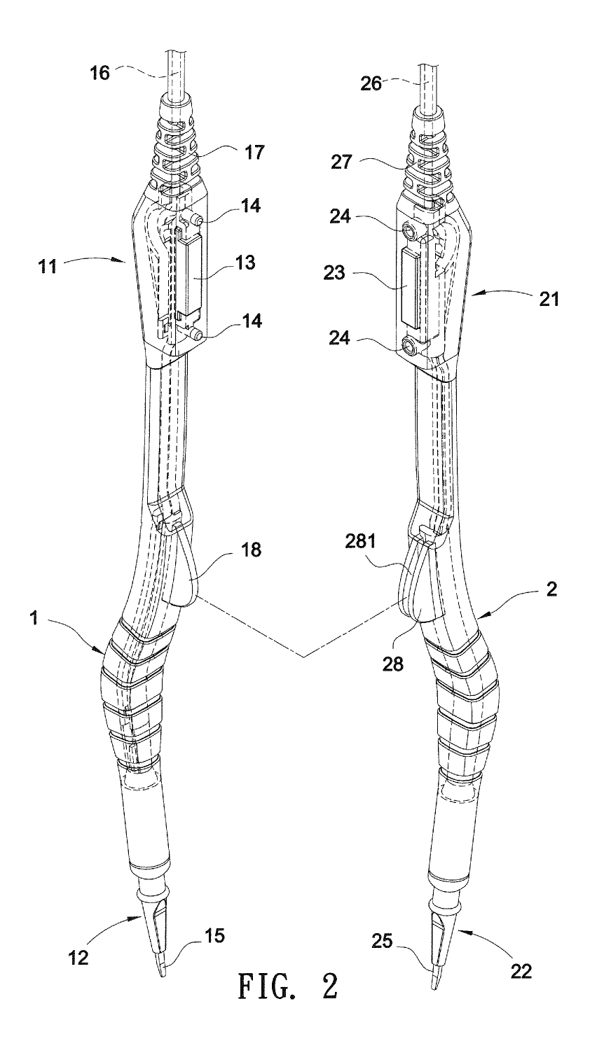

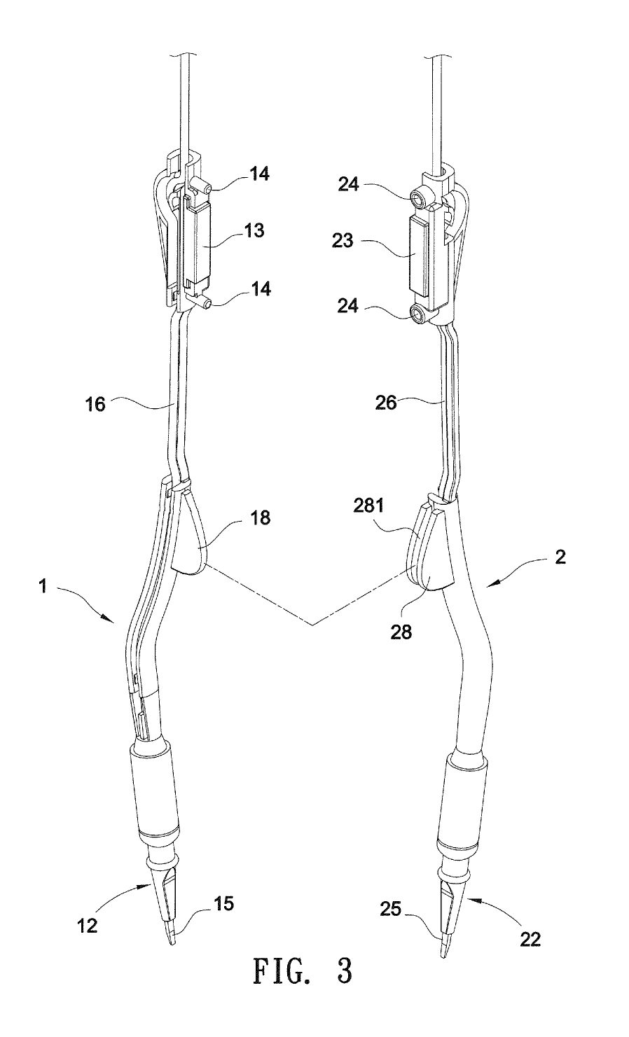

FIGS. 1 and 2 are perspective and break-down diagrams of a clamping and probing device according to an embodiment of the present invention. As illustrated, the clamping and probing device contains a first probing member 1 and a second probing member 2. The first probing member 1 contains a first coupling element 11 in an upper portion and a first probing element 12 at a bottom end of the first probing member 1. The first coupling element 11 has a first coupler 13 on a front side. In the present embodiment, the first coupler 13 is a magnet. At least a positioning pin 14 is configured on the front side around the first coupler 13. In the present embodiment, there are two positioning pins 14 above and below the first coupler 13, respectively. The first probing element 12 has a first probe 15 at a bottom end. The first probe 15 is electrically connected to a first cable 16 housed inside the first probing member 1. As shown in FIG. 3, the first cable 16 has one end connected to the first probe 15 and has the other end extended out of the first coupling element 16. A protective cover 17 wraps a section of the first cable 16 above the first coupling element 16. In a middle section and also on the front side of the first probing member 1, a plug element 18 is configured. In the present embodiment, the plug element 18 has a semicircular shape.

As illustrated in FIGS. 1 and 2, the second probing member 2 has a shape matching that o the firs probing member 1. The second probing member 2 contains a second coupling element 21 in an upper portion and a second probing element 22 at a bottom end of the second probing member 2. The second coupling element 21 has a second coupler 23 on a front side. In the present embodiment, the second coupler 23 is a magnet of a reversed polarity to that of the first coupler 13. By the magnetic attraction between the first and second couplers 13 and 23, the first and second probing members 1 and 2 are coupled together. At least a positioning hole 24 is configured on the front side around the second coupler 23. In the present embodiment, there are two positioning holes 24 above and below the second coupler 23, respectively, each corresponding to a positioning pin 14. When the first and second probing members 1 and 2 are coupled, the positioning pins 14 plug into the positioning holes 24, achieving a more reliable coupling between the first and second probing members 1 and 2. The second probing element 22 has a second probe 25 at a bottom end. The second probe 25 is electrically connected to a second cable 26 housed inside the second probing member 2. As shown in FIG. 3, the second cable 26 has one end connected to the second probe 25 and has the other end extended out of the second coupling element 26. A protective cover 27 wraps a section of the second cable 26 above the second coupling element 26. In a middle section and also on the front side of the second probing member 2, a socket element 28 is configured for coupling with the plug element 18. In the present embodiment, the socket element 28 has a semicircular shape with a slot 281 for receiving the plug element 18.

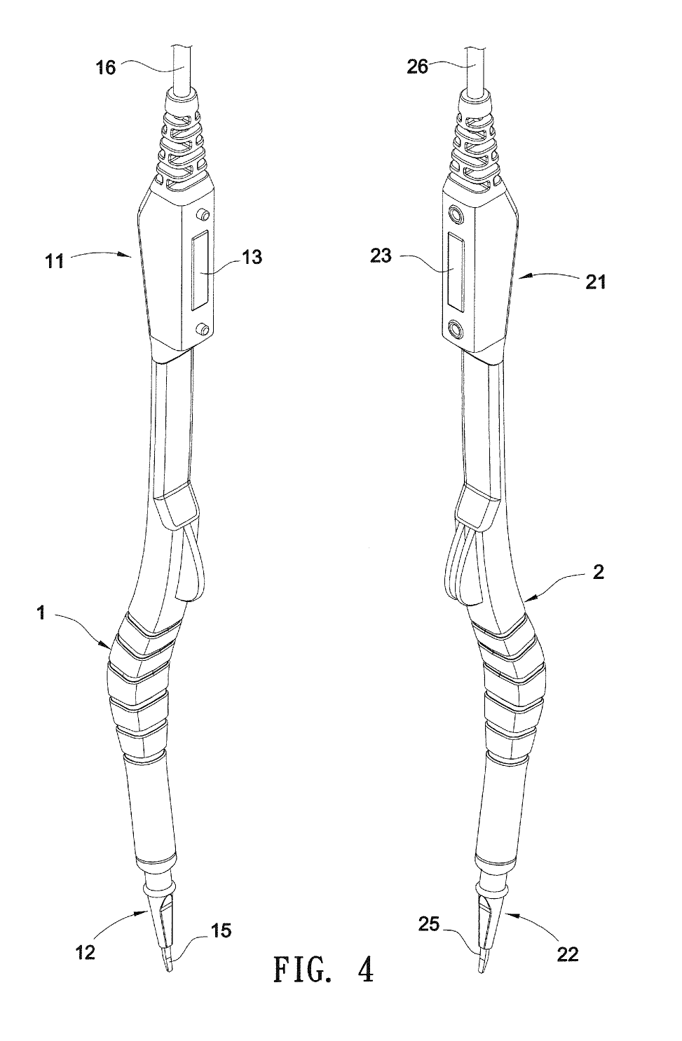

As shown in FIG. 4, when the first and second probing members 1 and 2 are separated, the first or second probing member 1 or 2 can function individually as a detection or measurement probe, using the first or second probe 15 and 25 of the first or second probing element 12 or 22 for detection or measurement on a printed circuit board.

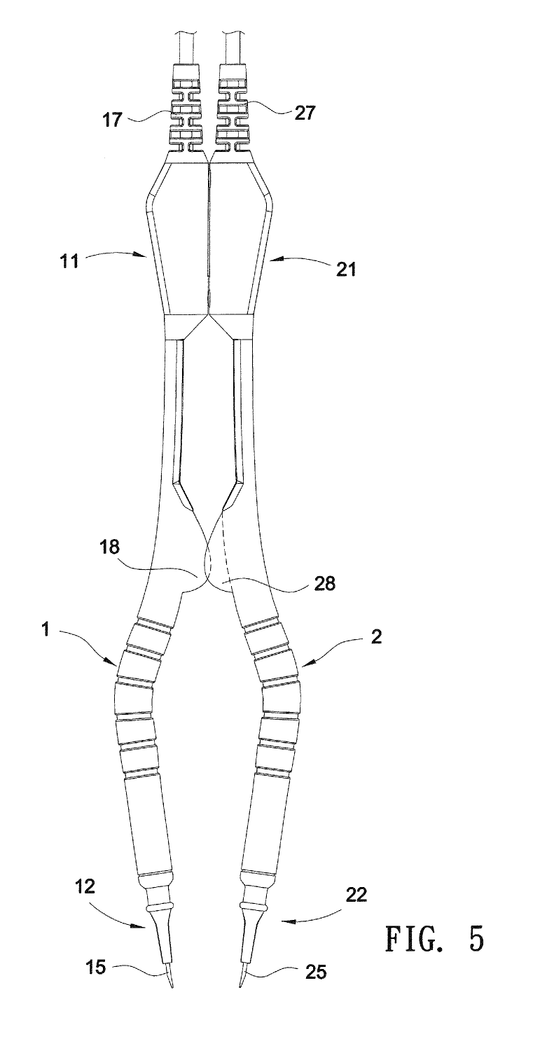

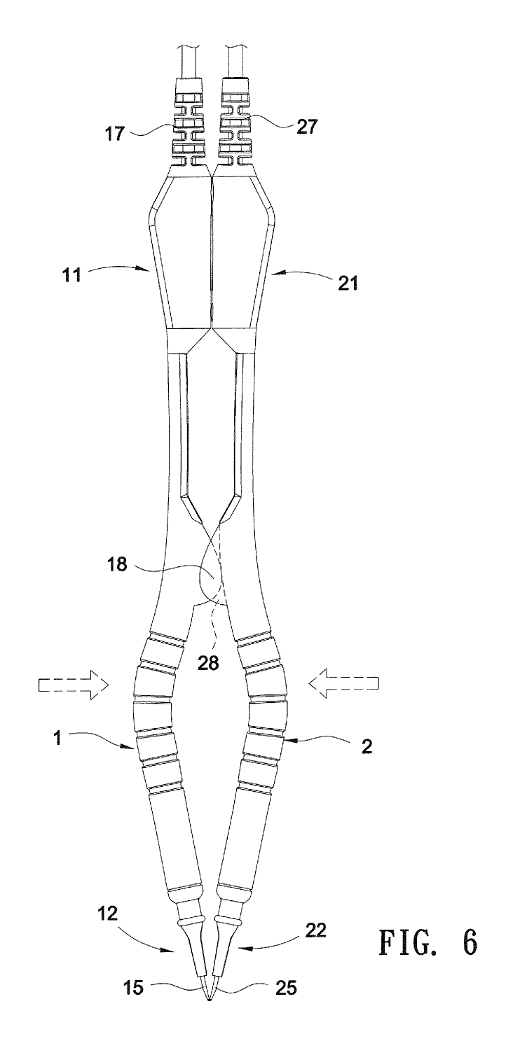

As shown FIG. 5, when the first coupler 13 of the first probing member 1 matches the second coupler 23 of the second probing member 2, the positioning pins 14 are plugged into the positioning holes 24, therefore reliably joining the first and second coupling elements 11 and 21 together. As shown in FIG. 6, the joined first and second coupling elements 11 and 21 can function as a pivot. By exerting force on the first and second probing members 1 and 2, the first and second probing elements 12 and 22 can be separated like a damper to clamp and test/measure small electronic component. When the first and second probing members 1 and 2 are moved towards each other, the plug element 18 on the first probing member 1 fits into the slot 281 of the socket element 29 on the second probing member 2, so as to reliably position the first and second probing members 1 and 2.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the claims of the present invention.

I claim:

1. A clamping and probing device comprising:
a first probing member comprising a first cable, a first coupler in an upper portion on a front side, and a first probe at a bottom end of the first probing member, where the first cable is housed inside the first probing member having one end connected to the first probe and another end extended out of a top end of the first probing member; and
a second probing member comprising a second cable, a second coupler in an upper portion on a front side, and a second probe at a bottom end of the second probing member, where the second cable is housed inside the second probing member having one end connected to the second probe and another end extended out of a top end of the second probing member.

2. The clamping and probing device according to claim 1, wherein the first and second couplers are magnets of reversed polarities.

3. The clamping and probing device according to claim 1, wherein a plurality of positioning pins are configured on the front side around the first coupler.

4. The clamping and probing device according to claim 3, wherein the positioning pins are configured above and below the first coupler, respectively.

5. The clamping and probing device according to claim 1, wherein a plurality of positioning holes are configured on the front side around the second couplet

6. The clamping and probing device according to claim 5, wherein the positioning holes are configured above and below the second coupler, respectively.

7. The clamping and probing device according to claim 1, wherein, in a middle section and on the front side of the first probing member, a plug element is configured.

8. The clamping and probing device according to claim 7, wherein, in a middle section and on the front side of the second probing member, a socket element is configured for coupling with the plug element.

9. The clamping and probing device according to claim 7, wherein the plug element has a semicircular shape.

10. The clamping and probing device according to claim 8, wherein the socket element has a slot for receiving the plug element.

11. The clamping and probing device according to claim 8, wherein the socket element has a semicircular shape.
